(19) United States
(12) Patent Application Publication
(10) Pub. No.: US 2003/0194825 A1
(43) Pub. Date: Oct. 16, 2003

(54) Deposition of gate metallization for active matrix liquid crystal display (AMLCD) applications

(76) Inventors: Kam Law, Union City, CA (US); Quan Yuan Shang, Saratoga, CA (US); William Reid Harshbarger, San Jose, CA (US); Dan Maydan, Los Altos Hills, CA (US)

Correspondence Address: Patent Counsel, Applied Materials, Inc., P.O. Box 450-A, Santa Clara, CA, 95052, US

(21) Appl. No.: 10/119,631

(22) Filed: Apr. 10, 2002

(51) Int. Cl. H01L 21/00; H01L 21/84

(52) U.S. Cl. 438/30; 438/158

(57) ABSTRACT

A method of gate metal layer deposition using a cyclical deposition process for thin film transistor applications is described. The cyclical deposition process comprises alternately adsorbing a metal-containing precursor and a reducing gas on a substrate. Thin film transistors, such as a bottom-gate transistor or a top-gate transistor, including a gate layer, may be formed using such cyclical deposition techniques.

### BACKGROUND OF THE INVENTION

1. Field of the Invention

Embodiments of the present invention relate to methods of gate metal layer deposition and, more particularly, to methods of gate metal layer formation using cyclical deposition techniques for active matrix liquid crystal display (AMLCD) applications.

2. Description of the Background Art

Active matrix liquid crystal displays have eliminated many problems associated with passive displays. For example, the fabrication of active matrix liquid crystal displays have enabled display screens to achieve greater brightness, enhanced readability, a greater variety of color shades, and broader viewing angles compared to displays that employ other technologies. Active matrix liquid crystal displays have therefore become the display technology of choice for numerous applications including computer monitors, television screens, camera displays, avionics displays, as well as numerous other applications.

Active matrix liquid crystal displays generally comprise an array of picture elements called pixels. An electronic switch is associated with each pixel in the display to control the operation thereof. Various electronic switches such as, for example, thin film transistors and organic light emitting diodes (OLED), among others have been investigated to control pixel operation. Thin film transistors, in particular, offer a high degree of design flexibility and device performance.

Thin film transistors are generally formed on large area substrates having a high degree of optical transparency such as, for example, glass. FIG. 1 depicts a cross-sectional schematic view of a thin film transistor 22 being a type that has a bottom gate structure. The thin film transistor 22 includes a glass substrate 1 having an underlayer 2 formed on the surface thereof. A gate is formed on the underlayer 2. The gate comprises a gate metal layer 4 and a gate dielectric layer 8. The gate controls the movement of charge carriers in the transistor. The gate dielectric layer 8 is formed over the gate metal layer 4 and electrically isolates the gate metal layer 4 from semiconductor layers 10, 14a, 14b, formed thereover, each of which may function to provide charge carriers to the transistor. A source region 18a of the transistor is formed on semiconductor layer 14a and a drain region 18b of the transistor is formed on semiconductor layer 14b. Finally, a passivation layer 20 encapsulates the thin film transistor 22 to protect it from environmental hazards such as moisture and oxygen.

The gate metal layer 4 generally comprises a conductive material (e.g., tungsten (W), aluminum (Al) chromium (Cr)), deposited using conventional techniques, such as, for example, physical vapor deposition (PVD). However, gate material layers deposited using PVD techniques generally tend to have high resistivities. For example, tungsten (W) layers deposited using PVD techniques typically have resistivities of greater than about 150 μΩ/cm. Such high resistivities for the gate metal layer may affect the electrical performance of the transistors, including device reliability and premature failure.

Therefore, a need exists to develop a method of forming gate metal layers for use in thin film transistors.

### SUMMARY OF THE INVENTION

A method of gate metal layer deposition for thin film transistor applications for use in active matrix liquid crystal displays (AMLCD) is described. The gate metal layer comprises a metal that is deposited using a cyclical deposition process. The cyclical deposition process comprises alternately adsorbing a metal-containing precursor and a reducing gas on a substrate structure. The adsorbed metal-containing precursor reacts with the adsorbed reducing gas to form the gate metal layer on the substrate.

Thin film transistors, such as for example a bottom-gate transistor or a top-gate transistor, including a gate metal layer may be formed using such cyclical deposition techniques. In one embodiment, a preferred process sequence for fabricating a bottom-gate transistor includes providing a substrate. A gate metal layer is deposited on the substrate. The gate metal layer is formed by alternately adsorbing a metal-containing precursor and a reducing gas on the substrate. The gate metal layer is than patterned and a gate dielectric layer is formed thereover. Source regions and drain regions are formed on the gate dielectric layer. Thereafter, the bottom-gate transistor may be completed by depositing a passivation layer on the substrate.

### BRIEF DESCRIPTION OF THE DRAWINGS

So that the manner in which the above recited features of the present invention are attained and can be understood in detail, a more particular description of the invention, briefly summarized above, may be had by reference to the embodiments thereof which are illustrated in the appended drawings.

It is to be noted, however, that the appended drawings illustrate only typical embodiments of this invention and are therefore not to be considered limiting of its scope, for the invention may admit to other equally effective embodiments.

FIG. 1 depicts a cross-sectional schematic view of a prior art bottom-gate thin film transistor;

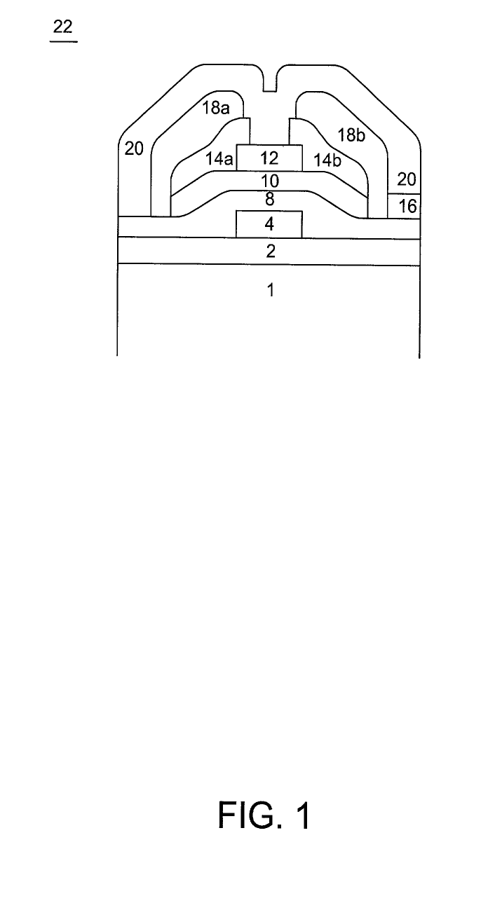

FIG. 2 depicts a schematic cross-sectional view of a process chamber that can be used to practice embodiments described herein;

FIG. 3 illustrates a process sequence for gate metal layer formation using cyclical deposition techniques according to one embodiment described herein;

FIG. 4 illustrates a process sequence for gate metal layer formation using cyclical deposition techniques according to an alternative embodiment described herein;

FIGS. 5A-5C depict cross-sectional views of a substrate at different stages of a bottom-gate thin film transistor fabrication sequence; and

FIGS. 6A-6C depict cross-sectional views of a substrate at different stages of a top-gate thin film transistor fabrication sequence.

### DETAILED DESCRIPTION OF THE INVENTION

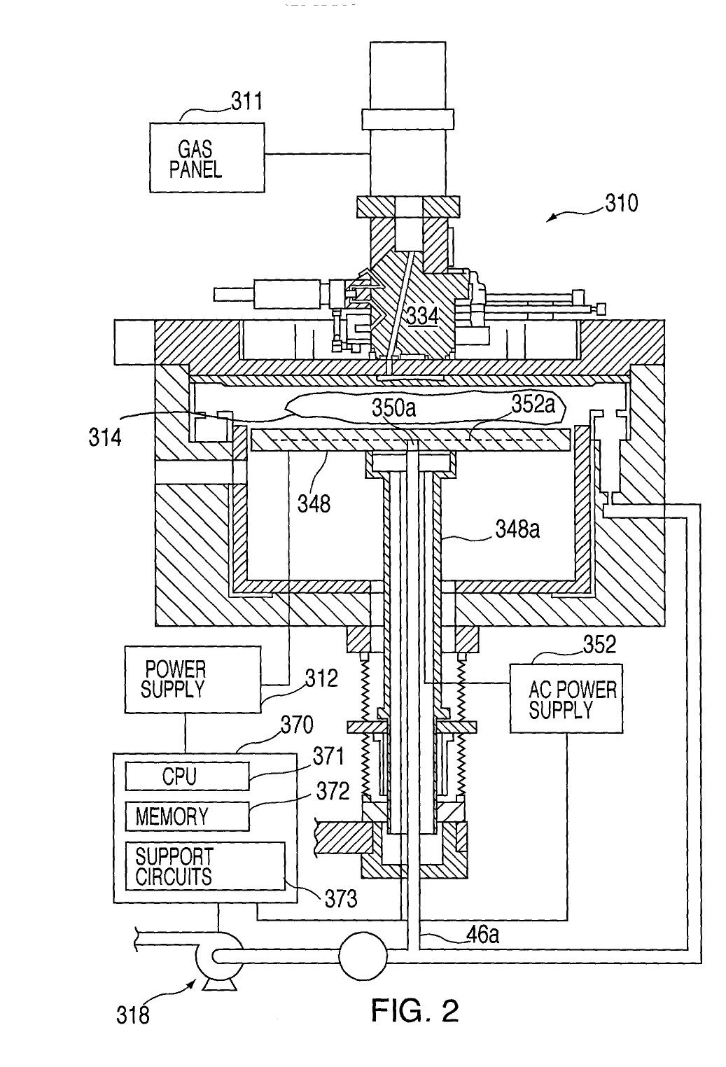

FIG. 2 depicts a schematic cross-sectional view of a process chamber 310 that can be used to perform integrated circuit fabrication in accordance with embodiments described herein. The process chamber 310 generally houses a substrate support pedestal 348, which is used to support a substrate (not shown). The substrate support pedestal 348 is movable in a vertical direction inside the process chamber 310 using a displacement mechanism 348a.

Depending on the specific process, the substrate can be heated to some desired temperature prior to or during deposition. For example, the substrate support pedestal 348 may be heated using an embedded heater element 352a. The substrate support pedestal 348 may be resistively heated by applying an electric current from an AC power supply 352 to the heater element 352a. The substrate (not shown) is, in turn, heated by the pedestal 348. Alternatively, the substrate support pedestal 348 may be heated using radiant heaters such as, for example, lamps (not shown).

A temperature sensor 350a, such as a thermocouple, is also embedded in the substrate support pedestal 348 to monitor the temperature of the pedestal 348 in a conventional manner. The measured temperature is used in a feedback loop to control the AC power supply 352 for the heating element 352a, such that the substrate temperature can be maintained or controlled at a desired temperature which is suitable for the particular process application.

A vacuum pump 318 is used to evacuate the process chamber 310 and to maintain the pressure inside the process chamber 310. A gas manifold 334, through which process gases are introduced into the process chamber 310, is located above the substrate support pedestal 348. The gas manifold 334 is connected to a gas panel 311, which controls and supplies various process gases to the process chamber 310.

Proper control and regulation of the gas flows to the gas manifold 334 are performed by mass flow controllers (not shown) and a microprocessor controller 370. The gas manifold 334 allows process gases to be introduced and uniformly distributed in the process chamber 310. Additionally, the gas manifold 334 may optionally be heated to prevent condensation of the any reactive gases within the manifold.

The gas manifold 334 includes a plurality of electronic control valves (not shown). The electronic control valves as used herein refer to any control valve capable of providing rapid and precise gas flow to the process chamber 310 with valve open and close cycles of less than about 1-2 seconds, and more preferably less than about 0.1 second.

The microprocessor controller 370 may be one of any form of general purpose computer processor (CPU) 371 that can be used in an industrial setting for controlling various chambers and sub-processors. The computer may use any suitable memory 372, such as random access memory, read only memory, floppy disk drive, hard disk, or any other form of digital storage, local or remote. Various support circuits 373 may be coupled to the CPU for supporting the processor in a conventional manner. Software routines as required may be stored on the memory or executed by a second CPU that is remotely located.

The software routines are executed to initiate process recipes or sequences. The software routines, when executed, transform the general purpose computer into a specific process computer that controls the chamber operation so that a chamber process is performed. For example, software routines may be used to precisely control the activation of the electronic control valves for the execution of process sequences according to the present invention. Alternatively, the software routines may be performed in hardware, as an application specific integrated circuit or other type of hardware implementation, or a combination of software or hardware.

Gate Metal Layer Formation

A method of forming a gate metal layer for thin film transistor applications is described. The gate metal layer comprises a metal that is deposited using a cyclical deposition process. The cyclical deposition process comprises alternately adsorbing a metal-containing precursor and a reducing gas on a substrate structure. The metal-containing precursor and the reducing gas react to form a gate metal layer on the substrate.

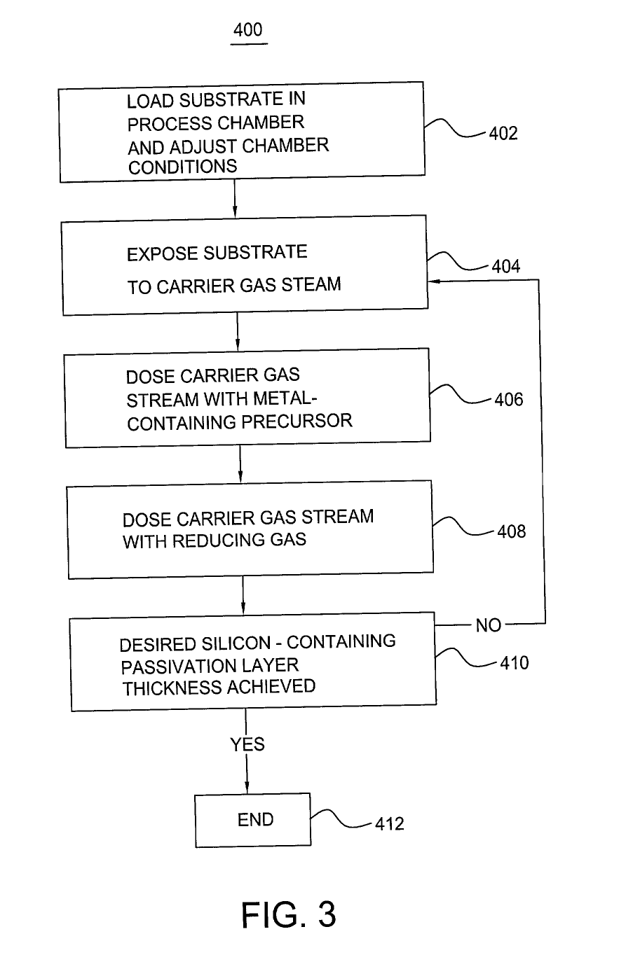

FIG. 3 illustrates a process sequence 400 detailing the various steps used for the deposition of the gate metal layer. These steps may be performed in a process chamber similar to that described above with reference to FIG. 2. As shown in step 402, a substrate is provided to the process chamber. The substrate may be for example, a glass or clear plastic material suitable for AMLCD fabrication. The process chamber conditions such as, for example, the temperature and pressure are adjusted to enhance the adsorption of the process gases on the substrate to facilitate the reaction of the metal-containing precursor and the reducing gas. In general, for gate metal layer deposition, the substrate should be maintained at a temperature between about 20° C. and about 450° C. at a process chamber pressure of between about 10 millitorr and about 10 torr.

In one embodiment where a constant carrier gas flow is desired, a carrier gas stream is established within the process chamber as indicated in step 404. Carrier gases may be selected so as to also act as a purge gas for removal of volatile reactants and/or by-products from the process chamber. Carrier gases such as, for example, helium (He), argon (Ar), and combinations thereof, may be used.

Referring to step 406, after the carrier gas stream is established within the process chamber, a pulse of a metal-containing precursor is added to the carrier gas stream. The term pulse as used herein refers to a dose of material injected into the process chamber or into the carrier gas stream. The pulse of the metal-containing precursor lasts for a predetermined time interval.

The metal-containing precursor may comprise a compound of a metal such as, for example, aluminum (Al), tungsten (W), molybdenum (Mo) and chromium (Cr), among others. A suitable aluminum (Al) precursor may include, for example, dimethyl aluminum hydride (DMAH). Suitable tungsten (W) precursors may include, for example, tungsten hexafluoride (WF₆) and tungsten hexacarbonyl (W(CO)₆). A suitable chromium (Cr) precursor may include, for example, chromium tetrachloride (CrCl₄).

The time interval for the pulse of the metal-containing precursor is variable depending upon a number of factors such as, for example, the volume capacity of the process chamber employed, the vacuum system coupled thereto and the volatility/reactivity of the reactants. For example, (1) a large-volume process chamber may lead to a longer time to stabilize the process conditions such as, for example, carrier/purge gas flow and temperature, requiring a longer pulse time; (2) a lower flow rate for the process gas may also lead to a longer time to stabilize the process conditions requiring a longer pulse time; and (3) a lower chamber pressure means that the process gas is evacuated from the process chamber more quickly requiring a longer pulse time. In general, the process conditions are advantageously selected so that a pulse of the metal-containing precursor provides a sufficient amount of precursor, such that at least a monolayer of the metal-containing precursor is adsorbed on the substrate. Thereafter, excess metal-containing precursor remaining in the chamber may be removed from the process chamber by the constant carrier gas stream in combination with the vacuum system.

In step 408, after the excess metal-containing precursor has been sufficiently removed from the process chamber by the carrier gas stream to prevent co-reaction or particle formation with a subsequently provided process gas, a pulse of a reducing gas is added to the carrier gas stream. Suitable reducing gases may include, for example, silane (SiH₄), disilane (Si₂H₆), dichlorosilane (SiCl₂H₂), ammonia (NH₃), hydrazine (N₂H₄), monomethyl hydrazine (CH₃N₂H₃), dimethyl hydrazine (C₂H₆N₂H₂), t-butyl hydrazine (C₄H₉N₂H₃), phenyl hydrazine (C₆H₅N₂H₃), 2,2′-azoisobutane ((CH₃)₆C₂N₂), ethylazide (C₂H₅N₃), borane (BH₃), diborane (B₂H₆), triborane (B₃H₉), tetraborane (B₄H₁₂), pentaborane (B₅H₁₅), hexaborane (B₆H₁₈), heptaborane (B₇H₂₁), octaborane (B₈H₂₄), nanoborane (B₉H₂₇) and decaborane (B₁₀H₃₀), among others.

The pulse of the reducing gas also lasts for a predetermined time interval. In general, the time interval for the pulse of the reducing gas should be long enough to provide a sufficient amount of the reducing gas for reaction with the metal-containing precursor that is already adsorbed on the substrate. Thereafter, excess reducing gas is flushed from the process chamber by the carrier gas stream.

Steps 404 through 408 comprise one embodiment of a deposition cycle for a gate metal layer. For such an embodiment, a constant flow of carrier gas is provided to the process chamber modulated by alternating periods of pulsing and non-pulsing where the periods of pulsing alternate between the metal-containing precursor and the reducing gas along with the carrier gas stream, while the periods of non-pulsing include only the carrier gas stream.

The time interval for each of the pulses of the metal-containing precursor and the reducing gas may have the same duration. That is the duration of the pulse of the metal-containing precursor may be identical to the duration of the pulse of the reducing gas. For such an embodiment, a time interval (T₁) for the pulse of the metal-containing precursor is equal to a time interval (T₂) for the pulse of the reducing gas.

Alternatively, the time interval for each of the pulses of the metal-containing precursor and the reducing gas may have different durations. That is the duration of the pulse of the metal-containing precursor may be shorter or longer than the duration of the pulse of the reducing gas. For such an embodiment, a time interval (T₁) for the pulse of the metal-containing precursor is different than a time interval (T₂) for the pulse of the reducing gas.

In addition, the periods of non-pulsing between each of the pulses of the metal-containing precursor and the reducing gas may have the same duration. That is the duration of the period of non-pulsing between each pulse of the metal-containing precursor and each pulse of the reducing gas is identical. For such an embodiment, a time interval (T₃) of non-pulsing between the pulse of the metal-containing precursor and the pulse of the reducing gas is equal to a time interval (T₄) of non-pulsing between the pulse of the reducing gas and the pulse of the metal-containing precursor. During the time periods of non-pulsing only the constant carrier gas stream is provided to the process chamber.

Alternatively, the periods of non-pulsing between each of the pulses of the metal-containing precursor and the reducing gas may have different durations. That is the duration of the period of non-pulsing between each pulse of the metal-containing precursor and each pulse of the reducing gas may be shorter or longer than the duration of the period of non-pulsing between each pulse of the reducing gas and the metal-containing precursor. For such an embodiment, a time interval (T₃) of non-pulsing between the pulse of the metal-containing precursor and the pulse of the reducing gas is different from a time interval (T₄) of non-pulsing between the pulse of the reducing gas and the pulse of the metal-containing precursor. During the time periods of non-pulsing only the constant carrier gas stream is provided to the process chamber.

Additionally, the time intervals for each pulse of the metal-containing precursor, the reducing gas and the periods of non-pulsing therebetween for each deposition cycle may have the same duration. For such an embodiment, a time interval (T₁) for the metal-containing precursor, a time interval (T₂) for the reducing gas, a time interval (T₃) of non-pulsing between the pulse of the metal-containing precursor and the pulse of the reducing gas and a time interval (T₄) of non-pulsing between the pulse of the reducing gas and the pulse of the metal-containing precursor each have the same value for each subsequent deposition cycle. For example, in a first deposition cycle (C₁), a time interval (T₁) for the pulse of the metal-containing precursor has the same duration as the time interval (T₁) for the pulse of the metal-containing precursor in subsequent deposition cycles (C₂ . . . C_{N}). Similarly, the duration of each pulse of the reducing gas and the periods of non-pulsing between the pulse of the metal-containing precursor and the reducing gas in deposition cycle (C₁) is the same as the duration of each pulse of the reducing gas and the periods of non-pulsing between the pulse of the metal-containing precursor and the reducing gas in subsequent deposition cycles (C₂ . . . C_{N}), respectively.

Alternatively, the time intervals for at least one pulse of the metal-containing precursor, the reducing gas and the periods of non-pulsing therebetween for one or more of the deposition cycles of the gate metal layer deposition process may have different durations. For such an embodiment, one or more of the time intervals (T₁) for the pulses of the metal-containing precursor, the time intervals (T₂) for the pulses of the reducing gas, the time intervals (T₃) of non-pulsing between the pulse of the metal-containing precursor and the pulse of the reducing gas and the time intervals (T₄) of non-pulsing between the pulse of the reducing gas and the pulse of the metal-containing precursor may have different values for one or more subsequent deposition cycles of the gate metal layer deposition process. For example, in a first deposition cycle (C₁), the time interval (T₁) for the pulse of the metal-containing precursor may be longer or shorter than the time interval (T₁) for the pulse of the metal-containing precursor in a subsequent deposition cycle (C₂ . . . C_{N}). Similarly, the duration of each pulse of the reducing gas and the periods of non-pulsing between the pulse of the metal-containing precursor and the reducing gas in deposition cycle (C₁) may be the same or different than the duration of each pulse of the reducing gas and the periods of non-pulsing between the pulse of the metal-containing precursor and the reducing gas in subsequent deposition cycles (C₂ . . . C_{N}), respectively.

Referring to step 410, after each deposition cycle (steps 404 through 408) a total thickness of the gate metal layer will be formed on the substrate. Depending on specific device requirements, subsequent deposition cycles may be needed to achieve a desired thickness. As such, steps 404 through 408 are repeated until the desired thickness for the gate metal layer is achieved. Thereafter, when the desired thickness for the gate metal layer is achieved the process is stopped as indicated by step 412.

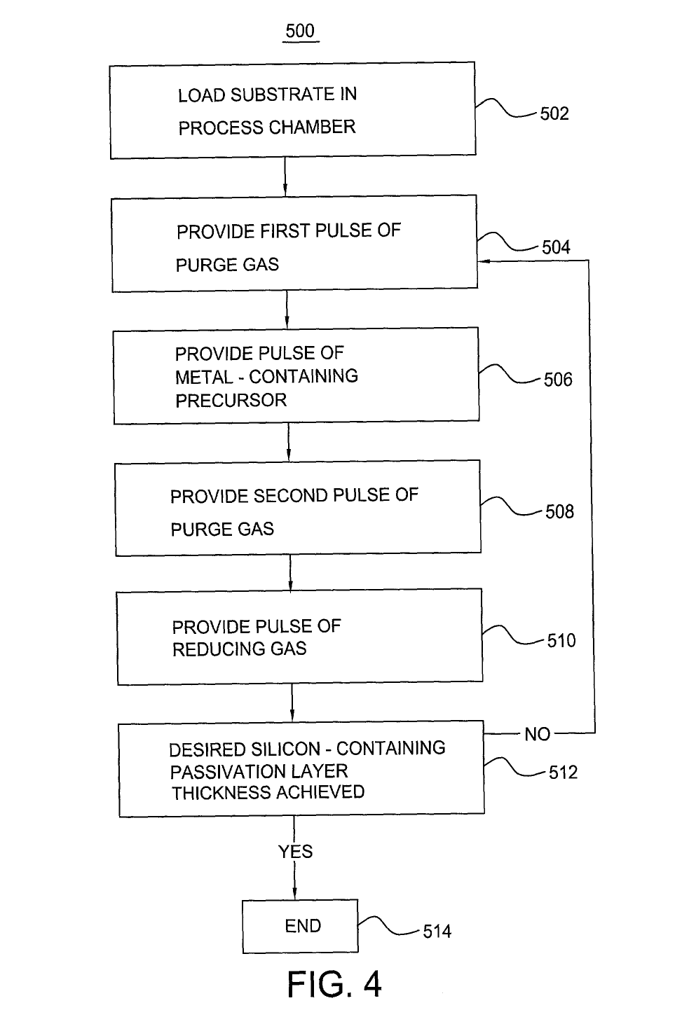

In an alternate process sequence described with respect to FIG. 4, the gate metal layer deposition cycle comprises separate pulses for each of the metal-containing precursor, the reducing gas, and the purge gas. For such an embodiment, the gate metal layer deposition sequence 500 includes providing a substrate to the process chamber (step 502), providing a first pulse of a purge gas to the process chamber (step 504), providing a pulse of a metal-containing precursor to the process chamber (step 506), providing a second pulse of the purge gas to the process chamber (step 508), providing a pulse of a reducing gas to the process chamber (step 510), and then repeating steps 504 through 510 or stopping the deposition process (step 514) depending on whether a desired thickness for the gate metal layer has been achieved (step 512).

The time intervals for each of the pulses of the metal-containing precursor, the reducing gas and the purge gas may have the same or different durations as discussed above with respect to FIG. 3. Alternatively, the time intervals for at least one pulse of the metal-containing precursor, the reducing gas and the purge gas for one or more of the deposition cycles of the gate metal layer deposition process may have different durations.

In FIGS. 3-4, the gate metal layer deposition cycle is depicted as beginning with a pulse of the metal-containing precursor followed by a pulse of the reducing gas. Alternatively, the gate metal layer deposition cycle may start with a pulse of the reducing gas followed by a pulse of the metal-containing precursor.

One exemplary process of depositing a tungsten gate layer comprises sequentially providing pulses of tungsten hexafluoride (WF₆) and pulses of diborane (B₂H₆). The tungsten hexafluoride (WF₆) may be provided to an appropriate flow control valve, for example, an electronic control valve, at a flow rate of between about 10 sccm (standard cubic centimeters per minute) and about 400 sccm, preferably between about 20 sccm and about 100 sccm, and thereafter pulsed for about 1 second or less, preferably about 0.2 seconds or less. A carrier gas comprising argon (Ar) is provided along with the tungsten hexaflouride (WF₆) at a flow rate between about 250 sccm to about 1000 sccm, preferably between about 500 sccm to about 750 sccm. The diborane (B₂H₆) may be provided to an appropriate flow control valve, for example, an electronic control valve, at a flow rate of between about 5 sccm and about 150 sccm, preferably between about 5 sccm and about 25 sccm, and thereafter pulsed for about 1 second or less, preferably about 0.2 seconds or less. A carrier gas comprising argon (Ar) is provided along with the diborane (B₂H₆) at a flow rate between about 250 sccm to about 1000 sccm, preferably between about 500 sccm to about 750 sccm. The substrate may be maintained at a temperature between about 250° C. and about 350° C., preferably about 300° C. at a chamber pressure between about 1 torr to about 10 torr, preferably about 5 torr.

Integrated Circuit Fabrication Processes

1. Bottom-Gate Thin Film Transistor

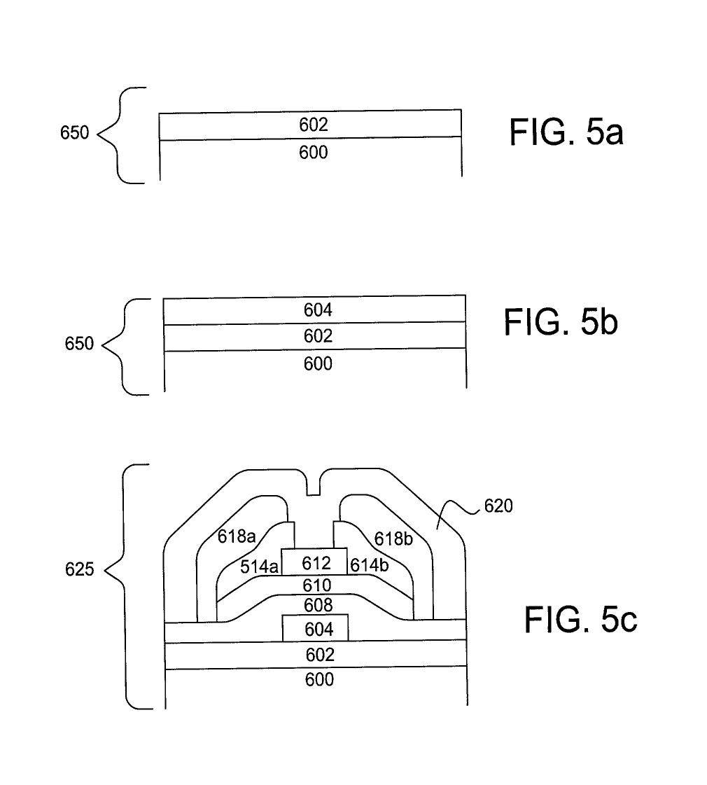

FIGS. 5A-5C illustrate cross-sectional schematic views of a substrate structure 650 during different stages of a bottom-gate thin film transistor fabrication sequence incorporating a gate metal layer formed using a cyclical deposition process. The transistor fabrication sequence is for a switch in an active matrix liquid crystal display (AMLCD) and this process depicts the formation of one of an array of switches used in an AMLCD. FIG. 5A, for example, illustrates a cross-sectional view of a substrate 600. The substrate 600 may comprise a material that is essentially optically transparent in the visible spectrum, such as, for example, glass or clear plastic, including soda-lime glass, borosilicate glass, or quartz glass. The substrate may be of varying shapes or dimensions. Typically, for thin film transistor applications, the substrate is a glass substrate with dimensions greater than about 500 mm×500 mm.

The substrate 600 may have an underlayer 602 thereon. The underlayer 602 may be an insulating material, for example, such as silicon dioxide (SiO₂) or silicon nitride (SiN). The underlayer 602 may be formed using conventional deposition techniques.

Referring to FIG. 5B, a gate metal layer 604a is deposited on the underlayer 602. The gate metal layer 604a is an electrically conductive layer that controls the movement of charge carriers within the thin film transistor. The gate metal layer 604a may comprise a metal such as, for example, aluminum (Al), tungsten (W), chromium (Cr) and molybdenum (Mo), among others. The gate metal layer 604a may be deposited using an embodiment of the cyclical deposition techniques as described above with reference to FIGS. 3-4. The gate metal layer 604a may be formed to a thickness in the range of about 1000 Angstroms to about 5000 Angstroms.

One or more gates 604 are formed in the gate metal layer 604a as shown in FIG. 5C. The one or more gates 604 may be formed using conventional lithography and etching techniques.

A gate dielectric layer 608 is formed on the one or more gates 604. The gate dielectric layer 608 may comprise, for example, silicon dioxide (SiO₂), silicon nitride (SiN), aluminum oxide (Al₂O₃) and tantalum oxide (Ta₂O₅), among others. Typically the gate dielectric layer 608 has a thickness in the range of about 20 Angstroms to about 5000 Angstroms.

A bulk semiconductor layer 610 is deposited on the gate dielectric layer 608. The bulk semiconductor layer 610 may be formed using conventional deposition techniques. The bulk semiconductor layer 610 may comprise, for example, amorphous silicon. The bulk semiconductor layer 610 may be have a thickness within a range of about 20 Angstroms to about 2000 Angstroms.

An etch stop layer 612 may be deposited on the bulk semiconductor layer 610. The etch stop layer 612 may comprise an insulating material. The etch stop layer 612 may be formed using, for example, plasma enhanced chemical vapor deposition, chemical vapor deposition, physical vapor deposition, or other conventional methods known to the art. The etch stop layer 612 and the bulk semiconductor layer 610 are lithographically patterned and etched using conventional techniques.

A doped semiconductor layer 614 is formed on the patterned etch stop layer 612 and the bulk semiconductor layer 610. The doped semiconductor layer 614 may comprise, for example, silicon. The doped semiconductor layer 614 may be deposited to a thickness within a range of about 10 Angstroms to about 100 Angstroms. The doped semiconductor layer 614 contacts portions of the bulk semiconductor layer 610, forming a semiconductor junction.

A transparent conductor layer 616 is formed on portions of the gate dielectric layer 608 and the doped semiconductor layer 614. The transparent conductor layer 616 comprises a material that is generally optically transparent in the visible spectrum and is electrically conductive. The transparent conductor layer 616 may comprise, for example, indium tin oxide (ITO), zinc oxide, among others. The transparent conductor layer 616 is lithographically patterned and etched using conventional techniques.

A conductive layer 618 is formed on the doped semiconductor layer 614 and the transparent conductor layer 616. The conductive layer 618 may comprise a metal such as, for example, aluminum (Al), tungsten (W), molybdenum (Mo), chromium (Cr), tantalum (Ta), and combinations thereof, among others. The conductive layer 618 may be formed using an embodiment of the cyclical deposition techniques as described above with reference to FIGS. 3-4. The conductive layer 618 may be formed to a thickness in the range of about 1000 Angstroms to about 5000 Angstroms.

Both the conductive layer 618 and the doped semiconductor layer 614 may be lithographically patterned to define a source region 614a and a drain region 614b as well as a source contact 618a and a drain contact 618b. The source 614a and drain 614b regions of the thin film transistor are separated from one another by the stop etch layer 612.

Thereafter, a passivation layer 620 may be deposited atop the substrate structure 650. The passivation layer 620 conformably coats exposed surfaces of gate dielectric layer 608, source contact 618a, drain contact 618band etch stop layer 612. The passivation layer 620 is generally an insulator and may comprise, for example, silicon oxide or silicon nitride. The passivation layer 620 may be formed using conventional deposition techniques.

2. Top-Gate Thin Film Transistor

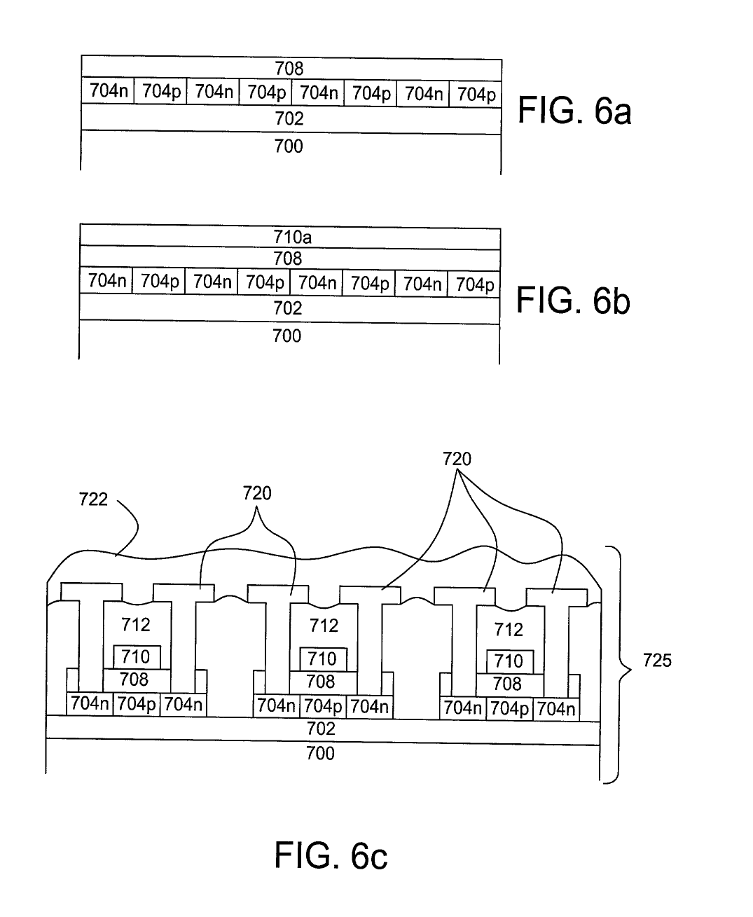

FIGS. 6A-6C illustrate cross-sectional schematic views of substrate structure 750 during different stages of a top-gate thin film transistor fabrication sequence incorporating a gate metal layer formed using a cyclical deposition process. The top-gate thin film transistor may be, for example, a metal-oxide-semiconductor field effect transistor (MOSFET) or a junction field effect transistor (JFET). This transistor fabrication sequence is for a switch in an active matrix liquid crystal display (AMLCD) and this process depicts the formation of one of an array of switches used in an AMLCD.

FIG. 6A, for example, illustrates a cross-sectional view of a substrate 700. The substrate may comprise a material that is essentially optically transparent in the visible spectrum, such as, for example, glass or clear plastic, including soda-lime glass, borosilicate glass, or quartz. The substrate may have an underlayer 702 thereon. The underlayer 702 may be an insulating material, such as, for example, silicon dioxide (SiO₂) or silicon nitride (SiN).

A doped semiconductor layer 704 is deposited on the underlayer 702. The doped semiconductor layer 704 may comprise silicon. The doped semiconductor layer 704 includes n-type doped regions 704n and p-type doped regions 704p. The interfaces between n-type doped regions 704n and p-type doped regions 704p are semiconductor junctions that support the ability of the thin film transistor (TFT) to act as a switching device.

A gate dielectric layer 708 is deposited on the n-type doped regions 704n and the p-type doped regions 704p. The gate dielectric layer 708 may comprise, for example, silicon oxide (SiO), aluminum oxide (Al₂O₃), and tantalum pentoxide (Ta₂O₅), among others. The gate dielectric layer 708 may be formed using conventional deposition processes.

Referring to FIG. 6B, a gate metal layer 710a is deposited on the gate dielectric layer 708. The gate metal layer 710a comprises an electrically conductive layer that controls the movement of charge carriers within the thin film transistor. The gate metal layer 710a may comprise a metal such as, for example, aluminum (Al), tungsten (W), chromium (Cr), molybdenum (Mo), or combinations thereof, among others.

The gate metal layer 710a may be formed using an embodiment of the cyclical deposition techniques as described above with reference to FIGS. 3-4. The gate metal layer 710a may be formed to a thickness in the range of about 1000 Angstroms to about 5000 Angstroms. After deposition the gate metal layer is patterned to define gates using conventional lithography and etching techniques.

One or more gates 710 are formed in the gate metal layer 710a as shown in FIG. 6C. The one or more gates 710 may be formed using conventional lithography and etching techniques.

After the gates 710 are formed, an interlayer dielectric 712 is formed thereon. The interlayer dielectric 712 may comprise, for example, an oxide such as silicon dioxide. The interlayer dielectric 712 may be formed using conventional deposition processes.

The interlayer dielectric 712 is patterned to expose the n-type doped regions 704n and the p-type doped regions 704p. The patterned regions of the interlayer dielectric 712 are filled with a conductive material to form contacts 720. The contacts 720 may comprise a metal such as, for example, aluminum (Al), tungsten (W), molybdenum (Mo) and chromium (Cr), among others. The contacts 720 may be formed using an embodiment of the cyclical deposition techniques as described above with reference to FIGS. 3-4.

Thereafter, a passivation layer 722 may be formed thereon in order to protect and encapsulate a completed thin film transistor 725. The passivation layer 722 is generally an insulator and may comprise, for example, silicon oxide or silicon nitride. The passivation layer 722 may be formed using conventional deposition techniques.

It is within the scope of the invention to form other devices that have configurations of semiconductor layers that are different from those described above with reference to FIGS. 5-6. For example, the switch for an AMLCD may be any variety of bipolar or unipolar transistor devices wherein a gate metal layer is deposited using the cyclical deposition process described herein.

While the foregoing is directed to the preferred embodiments of the present invention, other and further embodiments of the invention may be devised without departing from the basic scope thereof, and the scope thereof is determined by the claims that follow.

What is claimed is:

1. A method of forming a transistor for use in an active matrix liquid crystal display (AMLCD), comprising:
providing a substrate having a dielectric layer deposited over source regions and drain regions formed thereon; and
depositing a gate metal layer on the dielectric layer using a cyclical deposition process comprising a plurality of cycles, wherein each cycle comprises establishing a flow of an inert gas to a process chamber and modulating the flow of the inert gas with an alternating period of exposure to one of either a metal-containing precursor and a reducing gas.

2. The method of claim 1 wherein the gate metal layer comprises a material selected from the group consisting of aluminum (Al), tungsten (W), chromium (Cr) and molybdenum (Mo).

3. The method of claim 1 wherein the metal-containing precursor comprises a compound selected from the group consisting of dimethyl aluminum hydride (DMAH), tungsten hexafluoride (WF₆), tungsten hexacarbonyl (W(CO)₆) and chromium tetrachloride (CrCl₄).

4. The method of claim 1 wherein the reducing gas comprises a gas selected from the group consisting of silane (SiH₄), disilane (Si₂H₆), dichlorosilane (SiCl₂H₂), ammonia (NH₃), hydrazine (N₂H₄), monomethyl hydrazine (CH₃N₂H₃), dimethyl hydrazine (C₂H₆N₂H₂), t-butyl hydrazine (C₄H₉N₂H₃), phenyl hydrazine (C₆H₅N₂H₃), 2,2′-azoisobutane ((CH₃)₆C₂N₂) ethylazide (C₂H₅N₃), borane (BH₃), diborane (B₂H₆), triborane (B₃H₉), tetraborane (B₄H₁₂), pentaborane (B₅H₁₅), hexaborane (B₆H₁₈), heptaborane (B₇H₂₁), octaborane (B₈H₂₄), nanoborane (B₉H₂₇) and decaborane (B₁₀H₃₀).

5. A method of forming a transistor for use in an active matrix liquid crystal display (AMLCD), comprising:
providing a substrate;
depositing a gate metal layer on the substrate using a cyclical deposition process comprising a plurality of cycles, wherein each cycle comprises establishing a flow of an inert gas to a process chamber and modulating the flow of the inert gas with an alternating period of exposure to one of either a metal-containing precursor and a reducing gas;
defining one or more gates in the gate metal layer; and
forming source regions and drain regions over the one or more gates defined in the gate metal layer.

6. The method of claim 5 wherein the gate metal layer comprises a material selected from the group consisting of aluminum (Al), tungsten (W), chromium (Cr) and molybdenum (Mo).

7. The method of claim 5 wherein the metal-containing precursor comprises a compound selected from the group consisting of dimethyl aluminum hydride (DMAH), tungsten hexafluoride (WF₆), tungsten hexacarbonyl (W(CO)₆) and chromium tetrachloride (CrCl₄).

8. The method of claim 5 wherein the reducing gas comprises a gas selected from the group consisting of silane (SiH₄), disilane (Si₂H₆), dichlorosilane (SiCl₂H₂), ammonia (NH₃), hydrazine (N₂H₄), monomethyl hydrazine (CH₃N₂H₃), dimethyl hydrazine (C₂H₆N₂H₂), t-butyl hydrazine (C₄H₉N₂H₃), phenyl hydrazine (C₆H₅N₂H₃), 2,2′-azoisobutane ((CH₃)₆C₂N₂), ethylazide (C₂H₅N₃), borane (BH₃), diborane (B₂H₆), triborane (B₃H₉), tetraborane (B₄H₁₂), pentaborane (B₅H₁₅), hexaborane (B₆H₁₈), heptaborane (B₇H₂₁), octaborane (B₈H₂₄), nanoborane (B₉H₂₇) and decaborane (B₁₀H₃₀).

9. A method of forming a transistor for use in an active matrix liquid crystal display (AMLCD), comprising:
providing a substrate; and
depositing a gate metal layer on the substrate using a cyclical deposition process comprising a plurality of cycles, wherein each cycle comprises establishing a flow of an inert gas to a process chamber and modulating the flow of the inert gas with an alternating period of exposure to one of either a metal-containing precursor and a reducing gas.

10. The method of claim 9 wherein the period of exposure to the metal-containing precursor, the period of exposure to the reducing gas, a period of flow of the inert gas between the period of exposure to the metal-containing precursor and the period of exposure to the reducing gas, and a period of flow of the inert gas between the period of exposure to the reducing gas and the period of exposure to the metal-containing precursor each have the same duration.

11. The method of claim 9 wherein at least one of the period of exposure to the metal-containing precursor, the period of exposure to the reducing gas, a period of flow of the inert gas between the period of exposure to the metal-containing precursor and the period of exposure to the reducing gas, and a period of flow of the inert gas between the period of exposure to the reducing gas and the period of exposure to the metal-containing precursor has a different duration.

12. The method of claim 9 wherein the period of exposure to the metal-containing precursor during each deposition cycle of the cyclical deposition process has the same duration.

13. The method of claim 9 wherein at least one period of exposure to the metal-containing precursor for one or more deposition cycle of the cyclical deposition process has a different duration.

14. The method of claim 9 wherein the period of exposure to the reducing gas during each deposition cycle of the cyclical deposition process has the same duration.

15. The method of claim 9 wherein at least one period of exposure to the reducing gas for one or more deposition cycle of the cyclical deposition process has a different duration.

16. The method of claim 9 wherein a period of flow of the inert gas between the period of exposure to the metal-containing precursor and the period of exposure to the reducing gas during each deposition cycle of the cyclical deposition process has the same duration.

17. The method of claim 9 wherein at least one period of flow of the inert gas between the period of exposure to the metal-containing precursor and the period of exposure to the reducing gas for one or more deposition cycle of the cyclical deposition process has a different duration.

18. The method of claim 9 wherein a period of flow of the inert gas between the period of exposure to the reducing gas and the period of exposure to the metal-containing precursor during each deposition cycle of the cyclical deposition process has the same duration.

19. The method of claim 9 wherein at least one period of flow of the inert gas between the period of exposure to the reducing gas and the period of exposure to the metal-containing precursor for one or more deposition cycle of the cyclical deposition process has a different duration.

20. The method of claim 9 wherein the gate metal layer comprises a material selected from the group consisting of aluminum (Al), tungsten (W), chromium (Cr) and molybdenum (Mo).

21. The method of claim 9 wherein the metal-containing precursor comprises a compound selected from the group consisting of dimethyl aluminum hydride (DMAH), tungsten hexafluoride (WF₆), tungsten hexacarbonyl (W(CO)₆) and chromium tetrachloride (CrCl₄).

22. The method of claim 9 wherein the reducing gas comprises a gas selected from the group consisting of silane (SiH₄), disilane (Si₂H₆), dichlorosilane (SiCl₂H₂), ammonia (NH₃), hydrazine (N₂H₄), monomethyl hydrazine (CH₃N₂H₃), dimethyl hydrazine (C₂H₆N₂H₂), t-butyl hydrazine (C₄H₉N₂H₃), phenyl hydrazine (C₆H₅N₂H₃), 2,2′-azoisobutane ((CH₃)₆C₂N₂), ethylazide (C₂H₅N₃), borane (BH₃), diborane (B₂H₆), triborane (B₃H₉), tetraborane (B₄H₁₂), pentaborane (B₅H₁₅), hexaborane (B₆H₁₈), heptaborane (B₇H₂₁), octaborane (B₈H₂₄), nanoborane (B₉H₂₇) and decaborane (B₁₀H₃₀).

23. A method of forming a transistor for use in an active matrix liquid crystal display (AMLCD), comprising:
providing a substrate; and
depositing a gate metal layer on the substrate using a cyclical deposition process, wherein the cyclical deposition process includes a plurality of cycles, wherein each cycle comprises establishing a flow of an inert gas in a process chamber and modulating the flow of the inert gas with alternating periods of exposure to one of a metal-containing precursor and a reducing gas, and wherein the period of exposure to the metal-containing precursor, the period of exposure to the reducing gas, a period of flow of the inert gas between the period of exposure to the metal-containing precursor and the period of exposure to the reducing gas, and a period of flow of the inert gas between the period of exposure to the reducing gas and the period of exposure to the metal-containing precursor each have the same duration.

24. The method of claim 23 wherein the period of exposure to the metal-containing precursor during each deposition cycle of the cyclical deposition process has the same duration.

25. The method of claim 23 wherein at least one period of exposure to the metal-containing precursor for one or more deposition cycle of the cyclical deposition process has a different duration.

26. The method of claim 23 wherein the period of exposure to the reducing gas during each deposition cycle of the cyclical deposition process has the same duration.

27. The method of claim 23 wherein at least one period of exposure to the reducing gas for one or more deposition cycle of the cyclical deposition process has a different duration.

28. The method of claim 23 wherein a period of flow of the inert gas between the period of exposure to the metal-containing precursor and the reducing gas during each deposition cycle of the cyclical deposition process has the same duration.

29. The method of claim 23 wherein at least one period of flow of the inert gas between the period of exposure to the metal-containing precursor and the reducing gas during each deposition cycle of the cyclical deposition process has a different duration.

30. The method of claim 23 wherein a period of flow of the inert gas between the period of exposure to the reducing gas and the metal-containing precursor during each deposition cycle of the cyclical deposition process has the same duration.

31. The method of claim 23 wherein at least one period of flow of the inert gas between the period of exposure to the reducing gas and the metal-containing precursor for one or more deposition cycles of the cyclical deposition process has a different duration.

32. A method of forming a transistor for use in an active matrix liquid crystal display (AMLCD), comprising:
providing a substrate; and
depositing a gate metal layer on the substrate using a cyclical deposition process, wherein the cyclical deposition process includes a plurality of cycles, wherein each cycle comprises establishing a flow of an inert gas in a process chamber and modulating the flow of the inert gas with alternating periods of exposure to one of a metal-containing precursor and a reducing gas, and wherein at least one of the period of exposure to the metal-containing precursor, the period of exposure to the reducing gas, a period of flow of the inert gas between the period of exposure to the metal-containing precursor and the period of exposure to the reducing gas, and a period of flow of the inert gas between the period of exposure to the reducing gas and the period of exposure to the metal-containing precursor has a different duration.

33. The method of claim 32 wherein the period of exposure to the metal-containing precursor during each deposition cycle of the cyclical deposition process has the same duration.

34. The method of claim 32 wherein at least one period of exposure to the metal-containing precursor for one or more deposition cycle of the cyclical deposition process has a different duration.

35. The method of claim 32 wherein the period of exposure to the reducing gas during each deposition cycle of the cyclical deposition process has the same duration.

36. The method of claim 32 wherein at least one period of exposure to the reducing gas during one or more deposition cycle of the cyclical deposition process has a different duration.

37. The method of claim 32 wherein the period of flow of the inert gas between the period of exposure to the metal-containing precursor and the reducing gas during each deposition cycle of the cyclical deposition process has the same duration.

38. The method of claim 32 wherein at least one period of flow of the inert gas between the period of exposure to the metal-containing precursor and the reducing gas during each deposition cycle of the cyclical deposition process has a different duration.

39. The method of claim 32 wherein the period of flow of the inert gas between the period of exposure to the reducing gas and the metal-containing precursor during each deposition cycle of the cyclical deposition process has the same duration.

40. The method of claim 32 wherein at least one period of flow of the inert gas between the period of exposure to the reducing gas and the metal-containing precursor for one or more deposition cycles of the cyclical deposition process has a different duration.

41. A method of forming a transistor for use in an active matrix liquid crystal display (AMLCD), comprising:
providing a substrate; and
depositing a gate metal layer on the substrate using a cyclical deposition process, wherein the cyclical deposition process includes a plurality of cycles, wherein each cycle comprises establishing a flow of an inert gas in a process chamber and modulating the flow of the inert gas with alternating periods of exposure to one of a metal-containing precursor and a reducing gas, wherein the period of exposure to the metal-containing precursor, the period of exposure to the reducing gas, a period of flow of the inert gas between the period of exposure to the metal-containing precursor and the period of exposure to the reducing gas, and a period of flow of the inert gas between the period of exposure to the reducing gas and the period of exposure to the metal-containing precursor each have the same duration, and wherein the period of exposure to the metal-containing precursor, the period of exposure to the reducing gas, the period of flow of the inert gas between the period of exposure to the metal-containing precursor and the period of exposure to the reducing gas, and the period of flow of the inert gas between the period of exposure to the reducing gas and the period of exposure to the metal-containing precursor each have the same duration during each deposition cycle of the cyclical deposition process.

42. A method of forming a transistor for use in an active matrix liquid crystal display (AMLCD), comprising:
providing a substrate; and
depositing a gate metal layer on the substrate using a cyclical deposition process, wherein the cyclical deposition process includes a plurality of cycles, wherein each cycle comprises establishing a flow of an inert gas in a process chamber and modulating the flow of the inert gas with alternating periods of exposure to one of a metal-containing precursor and a reducing gas, wherein the period of exposure to the metal-containing precursor, the period of exposure to the reducing gas, a period of flow of the inert gas between the period of exposure to the metal-containing precursor and the period of exposure to the reducing gas, and a period of flow of the inert gas between the period of exposure to the reducing gas and the period of exposure to the metal-containing precursor each have the same duration, and wherein at least one of the period of exposure to the metal-containing precursor, the period of exposure to the reducing gas, the period of flow of the inert gas between the period of exposure to the metal-containing precursor and the period of exposure to the reducing gas, and the period of flow of the inert gas between the period of exposure to the reducing gas and the period of exposure to the metal-containing precursor has a different duration during one or more deposition cycles of the cyclical deposition process.

43. A method of forming a transistor for use in an active matrix liquid crystal display (AMLCD), comprising:
providing a substrate; and
depositing a gate metal layer on the substrate using a cyclical deposition process, wherein the cyclical deposition process includes a plurality of cycles, wherein each cycle comprises establishing a flow of an inert gas in a process chamber and modulating the flow of the inert gas with alternating periods of exposure to one of a metal-containing precursor and a reducing gas, wherein at least one of the period of exposure to the metal-containing precursor, the period of exposure to the reducing gas, a period of flow of the inert gas between the period of exposure to the metal-containing precursor and the period of exposure to the reducing gas, and a period of flow of the inert gas between the period of exposure to the reducing gas and the period of exposure to the metal-containing precursor has a different duration, and wherein the period of exposure to the metal-containing precursor, the period of exposure to the reducing gas, the period of flow of the inert gas between the period of exposure to the metal-containing precursor and the period of exposure to the reducing gas, and the period of flow of the inert gas between the period of exposure to the reducing gas and the period of exposure to the metal-containing precursor each have the same duration during each deposition cycle of the cyclical deposition process.

44. A method of forming a transistor for use in an active matrix liquid crystal display (AMLCD), comprising:
providing a substrate; and
depositing a gate metal layer on the substrate using a cyclical deposition process, wherein the cyclical deposition process includes a plurality of cycles, wherein each cycle comprises establishing a flow of an inert gas in a process chamber and modulating the flow of the inert gas with alternating periods of exposure to one of a metal-containing precursor and a reducing gas, wherein at least one of the period of exposure to the metal-containing precursor, the period of exposure to the reducing gas, a period of flow of the inert gas between the period of exposure to the metal-containing precursor and the period of exposure to the reducing gas, and a period of flow of the inert gas between the period of exposure to the reducing gas and the period of exposure to the metal-containing precursor has a different duration, and wherein at least one of the period of exposure to the metal-containing precursor, the period of exposure to the reducing gas, the period of flow of the inert gas between the period of exposure to the metal-containing precursor and the period of exposure to the reducing gas, and the period of flow of the inert gas between the period of exposure to the reducing gas and the period of exposure to the silicon-containing precursor has a different duration during one or more deposition cycles of the cyclical deposition process.

45. A method of forming a gate metal layer on a substrate, comprising:
providing a substrate; and
depositing a gate metal layer on the substrate using a cyclical deposition process comprising a plurality of cycles, wherein each cycle comprises establishing a flow of an inert gas to a process chamber and modulating the flow of the inert gas with an alternating period of exposure to one of either a metal-containing precursor and a reducing gas.

46. The method of claim 45 wherein the period of exposure to the metal-containing precursor, the period of exposure to the reducing gas, a period of flow of the inert gas between the period of exposure to the metal-containing precursor and the period of exposure to the reducing gas, and a period of flow of the inert gas between the period of exposure to the reducing gas and the period of exposure to the metal-containing precursor each have the same duration.

47. The method of claim 45 wherein at least one of the period of exposure to the metal-containing precursor, the period of exposure to the reducing gas, a period of flow of the inert gas between the period of exposure to the metal-containing precursor and the period of exposure to the reducing gas, and a period of flow of the inert gas between the period of exposure to the reducing gas and the period of exposure to the metal-containing precursor has a different duration.

48. The method of claim 45 wherein the period of exposure to the metal-containing precursor during each deposition cycle of the cyclical deposition process has the same duration.

49. The method of claim 45 wherein at least one period of exposure to the metal-containing precursor for one or more deposition cycle of the cyclical deposition process has a different duration.

50. The method of claim 45 wherein the period of exposure to the reducing gas during each deposition cycle of the cyclical deposition process has the same duration.

51. The method of claim 45 wherein at least one period of exposure to the reducing gas for one or more deposition cycle of the cyclical deposition process has a different duration.

52. The method of claim 45 wherein a period of flow of the inert gas between the period of exposure to the metal-containing precursor and the period of exposure to the reducing gas during each deposition cycle of the cyclical deposition process has the same duration.

53. The method of claim 45 wherein at least one period of flow of the inert gas between the period of exposure to the metal-containing precursor and the period of exposure to the reducing gas for one or more deposition cycle of the cyclical deposition process has a different duration.

54. The method of claim 45 wherein a period of flow of the inert gas between the period of exposure to the reducing gas and the period of exposure to the metal-containing precursor during each deposition cycle of the cyclical deposition process has the same duration.

55. The method of claim 45 wherein at least one period of flow of the inert gas between the period of exposure to the reducing gas and the period of exposure to the metal-containing precursor for one or more deposition cycle of the cyclical deposition process has a different duration.

56. The method of claim 45 wherein the gate metal layer comprises a material selected from the group consisting of aluminum (Al), tungsten (W), chromium (Cr) and molybdenum (Mo).

57. The method of claim 45 wherein the metal-containing precursor comprises a compound selected from the group consisting of dimethyl aluminum hydride (DMAH), tungsten hexafluoride (WF₆), tungsten hexacarbonyl (W(CO)₆) and chromium tetrachloride (CrCl₄).

58. The method of claim 45 wherein the reducing gas comprises a gas selected from the group consisting of silane (SiH₄), disilane (Si₂H₆), dichlorosilane (SiCl₂H₂), ammonia (NH₃), hydrazine (N₂H₄), monomethyl hydrazine (CH₃N₂H₃), dimethyl hydrazine (C₂H₆N₂H₂), t-butyl hydrazine (C₄H₉N₂H₃), phenyl hydrazine (C₆H₅N₂H₃), 2,2′-azoisobutane ((CH₃)₆C₂N₂), ethylazide (C₂H₅N₃), borane (BH₃), diborane (B₂H₆), triborane (B₃H₉), tetraborane (B₄H₁₂), pentaborane (B₅H₁₅), hexaborane (B₆H₁₈), heptaborane (B₇H₂₁), octaborane (B₈H₂₄), nanoborane (B₉H₂₇) and decaborane (B₁₀H₃₀).

59. A transistor for use in an active matrix liquid crystal display (AMLCD), comprising:
a substrate a gate metal layer formed thereon, the gate metal layer is formed using a cyclical deposition process comprising a plurality of cycles, wherein each cycle comprises establishing a flow of an inert gas to a process chamber and modulating the flow of the inert gas with an alternating period of exposure to one of either a metal-containing precursor and a reducing gas.

60. The transistor of claim 59 wherein the period of exposure to the metal-containing precursor, the period of exposure to the reducing gas, a period of flow of the inert gas between the period of exposure to the metal-containing precursor and the period of exposure to the reducing gas, and a period of flow of the inert gas between the period of exposure to the reducing gas and the period of exposure to the metal-containing precursor each have the same duration.

61. The transistor of claim 59 wherein at least one of the period of exposure to the metal-containing precursor, the period of exposure to the reducing gas, a period of flow of the inert gas between the period of exposure to the metal-containing precursor and the period of exposure to the reducing gas, and a period of flow of the inert gas between the period of exposure to the reducing gas and the period of exposure to the metal-containing precursor has a different duration.

62. The transistor of claim 59 wherein the period of exposure to the metal-containing precursor during each deposition cycle of the cyclical deposition process has the same duration.

63. The transistor of claim 59 wherein at least one period of exposure to the metal-containing precursor for one or more deposition cycle of the cyclical deposition process has a different duration.

64. The transistor of claim 59 wherein the period of exposure to the reducing gas during each deposition cycle of the cyclical deposition process has the same duration.

65. The transistor of claim 59 wherein at least one period of exposure to the reducing gas for one or more deposition cycle of the cyclical deposition process has a different duration.

66. The transistor of claim 59 wherein a period of flow of the inert gas between the period of exposure to the metal-containing precursor and the period of exposure to the reducing gas during each deposition cycle of the cyclical deposition process has the same duration.

67. The transistor of claim 59 wherein at least one period of flow of the inert gas between the period of exposure to the metal-containing precursor and the period of exposure to the reducing gas for one or more deposition cycle of the cyclical deposition process has a different duration.

68. The transistor of claim 59 wherein a period of flow of the inert gas between the period of exposure to the reducing gas and the period of exposure to the metal-containing precursor during each deposition cycle of the cyclical deposition process has the same duration.

69. The transistor of claim 59 wherein at least one period of flow of the inert gas between the period of exposure to the reducing gas and the period of exposure to the metal-containing precursor for one or more deposition cycle of the cyclical deposition process has a different duration.

70. The transistor of claim 59 wherein the gate metal layer comprises a material selected from the group consisting of aluminum (Al), tungsten (W), chromium (Cr) and molybdenum (Mo).

71. The transistor of claim 59 wherein the metal-containing precursor comprises a compound selected from the group consisting of dimethyl aluminum hydride (DMAH), tungsten hexafluoride (WF₆), tungsten hexacarbonyl (W(CO)₆) and chromium tetrachloride (CrCl₄).

72. The transistor of claim 59 wherein the reducing gas comprises a gas selected from the group consisting of silane (SiH₄), disilane (Si₂H₆), dichlorosilane (SiCl₂H₂), ammonia (NH₃), hydrazine (N₂H₄), monomethyl hydrazine (CH₃N₂H₃), dimethyl hydrazine (C₂H₆N₂H₂), t-butyl hydrazine (C₄H₉N₂H₃), phenyl hydrazine (C₆H₅N₂H₃), 2,2′-azoisobutane ((CH₃)₆C₂N₂), ethylazide (C₂H₅N₃), borane (BH₃), diborane (B₂H₆), triborane (B₃H₉), tetraborane (B₄H₁₂), pentaborane (B₅H₁₅), hexaborane (B₆H₁₈), heptaborane (B₇H₂₁), octaborane (B₈H₂₄), nanoborane (B₉H₂₇) and decaborane (B₁₀H₃₀).
